(19) United States
(12) Patent Application Publication
(10) Pub. No.: US 2025/0079392 A1
(43) Pub. Date: Mar. 6, 2025

(54) HYBRID BONDING INTERCONNECT (HBI) ARCHITECTURES AND METHODS FOR SCALABILITY

(71) Applicant: Intel Corporation, Santa Clara, CA (US)

(72) Inventors: Omkar G. Karhade, Chandler, AZ (US); Nitin A. Deshpande, Chandler, AZ (US); Mohammad Enamul Kabir, Portland, OR (US); Debendra Mallik, Chandler, AZ (US)

(73) Assignee: Intel Corporation, Santa Clara, CA (US)

(21) Appl. No.: 18/458,621

(22) Filed: Aug. 30, 2023

(51) Int. Cl. H01L 23/00; H01L 25/065

(52) U.S. Cl. CPC H01L 24/80; H01L 23/564; H01L 24/05; H01L 24/08; H01L 24/16; H01L 25/0652; H01L 25/0657; H01L 2224/05541; H01L 2224/05647; H01L 2224/08145; H01L 2224/16225; H01L 2224/80357; H01L 2224/80379; H01L 2924/04642; H01L 2924/0504; H01L 2924/059

(57) ABSTRACT

Hybrid bonding interconnect (HBI) architectures for scalability. Embodiments implement a bonding layer on a semiconductor die that includes a thick oxide layer overlaid with a thin layer of a hermetic material including silicon and at least one of carbon and nitrogen. The conductive bonds of the semiconductor die are placed in the thick oxide layer and exposed at the surface of the hermetic material. Some embodiments implement a non-bonding moisture seal ring (MSR) structure.

### BACKGROUND

Hybrid bonding interconnect (HBI) is a packaging technology involving electrical and mechanical connection between two semiconductor devices. To HBI bond two semiconductor devices together, the surfaces of the semiconductor devices are brought together under applied pressure and/or at elevated temperature, resulting in dielectric-to-dielectric bonding and metal-to-metal bonding. However, HBI presents some technical challenges, and improvements to HBI methods and architectures are desirable.

### BRIEF DESCRIPTION OF THE DRAWINGS

FIG. 1A illustrates two different semiconductor dies that implement the hybrid bonding interconnect (HBI) architectures described herein.

FIG. 1B provides an example multi-die assembly including the semiconductor dies of FIG. 1A hybrid fusion bonded together, in accordance with various embodiments.

FIG. 2 provides a simplified zoomed-in image of the multi-die assembly of FIG. 1B.

FIG. 3 illustrates another multi-die assembly embodiment, in which the structures used for moisture sealing at the periphery of a semiconductor die are omitted, in accordance with various embodiments.

FIG. 4 provides a schematic illustration of a cross-sectional view of an example integrated circuit device (e.g., as may be found in a semiconductor die), according to some embodiments of the present disclosure.

FIG. 5 and FIG. 6 depict examples of the disclosed HBI architectures as they may be implemented in various packages and devices.

FIG. 7 illustrates example process steps for a method for manufacturing and implementing a HBI bonded semiconductor assembly with the disclosed HBI architecture, in accordance with various embodiments.

FIG. 8 is a top view of a wafer and dies that may be included in a microelectronic assembly, in accordance with any of the embodiments disclosed herein.

FIG. 10A to FIG. 10D are simplified perspective views of example planar, FinFET, gate-all-around, and stacked gate-all-around transistors, as may be implemented in various embodiments.

FIG. 9 is a simplified cross-sectional side view showing an implementation of an integrated circuit on a die that may be included in various embodiments, in accordance with any of the embodiments disclosed herein.

FIG. 11 is a cross-sectional side view of a microelectronic assembly that may include any of the embodiments disclosed herein.

FIG. 12 is a block diagram of an example electrical device that may include any of the embodiments disclosed herein.

### DETAILED DESCRIPTION

It is desirable that the bond between two bonded semiconductor devices be impervious to gas flow or have a quality of hermeticity. Gas flow, and specifically, moisture flow, can aggravate copper (Cu) migration. As mentioned, Hybrid bonding interconnect (HBI) is a packaging technology that involves bringing together the surfaces of two semiconductor devices under applied pressure and/or at elevated temperature, resulting in dielectric-to-dielectric bonding and metal-to-metal bonding.

HBI advantageously enables “small” pitches (defined herein as a pitch less than 10 microns +/−10%, and in some cases, the pitch is less than 1 micron +/−10%). However, at these small pitches, with available placement and manufacturing tolerances, the pad-to-pad distance can become prone to Cu migration through the bonding layer dielectric. In some scenarios, this small pitch threshold leading to Cu migration is less than 2 microns. A technical problem is presented in that the presence of moisture increases the risk of Cu migration and corrosion at these small pitches.

Bonding can also present a technical challenge for HBI. In hybrid bonding, the dielectric is bonded first with recessed Cu for conductive pads on the upper surfaces of the two semiconductor dies. The temperature annealing process of HBI causes the Cu of a conductive pad of a first semiconductor die to expand and diffuse, meeting with the Cu from the respective conductive pad on the upper surface of the second semiconductor die.

Proposed solutions to these technical challenges have included using a thicker dielectric or oxide layer, which enables creating “taller” conductive pads for bonding. As used herein, the “thicker” oxide is 4 microns +/−20%. Copper expansion is higher for taller Cu pads, which can be beneficial for the Cu diffusion between conductive pads on corresponding die, however this can be problematic, as a tighter pad recess spec or pitch can increase a yield loss during chemical mechanical processing (CMP).

Other solutions implement a copper wall or other structure to create a moisture seal ring (MSR) or barrier around the conductive pads. For proper operation of a MSR (to adequately resist moisture flow post assembly) the structure or MSR in the first semiconductor die must be bonded to a respective structure or MSR in a second semiconductor die. This MSR alignment can be technically challenging because the MSR structures generally have different geometries than that of the conductive pads, and a misalignment between them can lead to an increased Cu migration between conductive pads.

Another solution implements a thin nitride or silicon-carbon-nitride (SiCN) dielectric as a bonding layer and surface layer on the semiconductor dies. As used here, this thin layer may be less than two microns. This approach can improve moisture flow and reduce Cu migration; however, it is difficult to manufacture conductive pads of sufficient height in this process because of the slower deposition process and higher stress.

Accordingly, while the above approaches have made some improvements in HBI, there is a need for a recipe of materials and geometries to improve HBI bondability and moisture resistance that is scalable.

Embodiments disclosed herein propose a technical solution to the above-described technical problems in the form of hybrid bonding interconnect (HBI) architectures for scalability. Proposed embodiments implement a thick oxide layer (or dielectric layer) for the conductive bonds between two semiconductor dies and a hermetic or moisture flow resistant surface layer on the semiconductor dies. Some embodiments implement a non-bonding MSR. These concepts are developed in more detail below.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

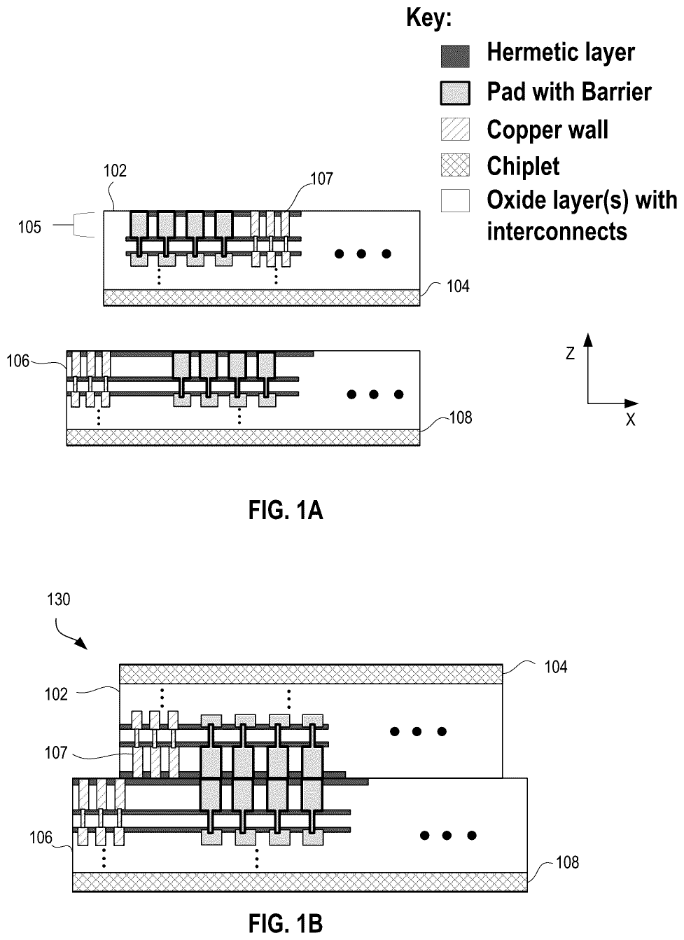

FIG. 1A and FIG. 1B illustrate portions of side views (using a Z-X frame of reference) of two different semiconductor dies (102, 106) that implement the hybrid bonding interconnect (HBI) architectures described herein. The semiconductor die 102 includes a chiplet region 104 of front-end-of-line (FEOL) semiconductor processing and structures where the individual devices (e.g., integrated circuitry, such as, transistors, capacitors, resistors, etc.) are patterned in the semiconductor substrate or layer. The chiplet region 104 may then be overlaid with oxide layers and conductive interconnects, over which a bonding layer 105 forms an upper surface.

The bonding layer 105 includes therein at least one conductive pad that is coupled to the integrated circuitry of the chiplet region 104 and exposed at the upper surface, as shown. The periphery of the conductive pads may have a barrier material to protect them, which looks like a perimeter comprising a thin metal layer, and the thin metal layer comprises a different material than a material that the conductive pad comprises. In various embodiments, the barrier material is a metal. In various aspects of the disclosure, the bonding layer 105 further includes a structure 107 that extends upward from the chiplet region 104. The structure 107, when viewed from a top-down view, may surround the integrated circuitry like a ring or series of connected rings (e.g., the MSR described above). Viewed from the side view, as shown in FIG. 1A, the structure 107 is contiguous through the bonding layer 105 and is exposed at the surface. In various embodiments, the structure 107 is a copper wall.

As shown in FIG. 1A, the second semiconductor die 106 may include the same architectural features described above in connection with the first semiconductor die 102. By implementing the provided hybrid bonding interconnect (HBI) architectures on the first semiconductor die 102 and the second semiconductor die 106, a multi-die assembly can be created with the hybrid bonding procedure.

FIG. 1B illustrates a portion of a left side of an example multi-die assembly 130 that implements the provided hybrid bonding interconnect (HBI) architecture with the first semiconductor die 102 and the second semiconductor die 106. The chiplet region 108 of the second semiconductor die 106 has overlaid thereon the oxide layers, structure, conductive pads, and hermetic materials as described for the first semiconductor die 102. As may be appreciated, this arrangement of die is just one example embodiment, in other multi-die assemblies; there may be more or less semiconductor dies, and the dies may have various sizes and shapes.

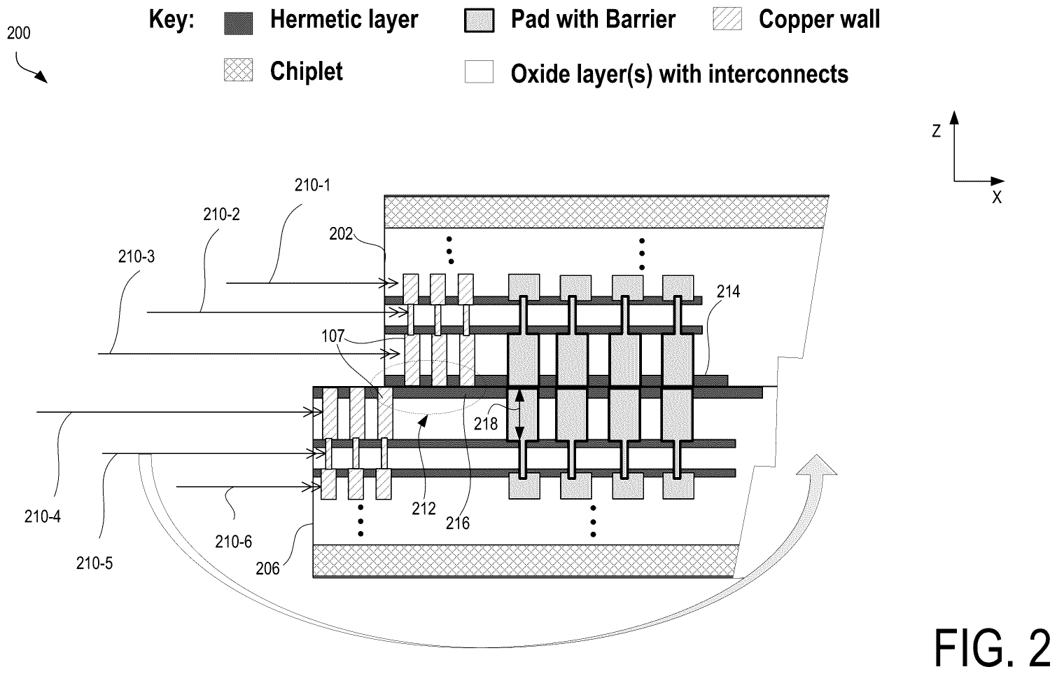

FIG. 2 provides a simplified zoomed-in image of the left side portion of the multi-die assembly 130/200 comprising semiconductor die 102/202 and semiconductor die 106/206. The structure 107 is part or all of a moisture seal ring (MSR) in the semiconductor die 102/202 and/or 106/206. In practice, each semiconductor die may have a three-dimensional MSR that extends completely around the perimeter of the die/logic. In a non-limiting example, the structure 107 is part of a copper wall comprising three rings. However, other embodiments may implement a moisture seal ring (MSR) with a different number of structures or rings, and the MSR of a first die does not have to be the same as a MSR of a second die.

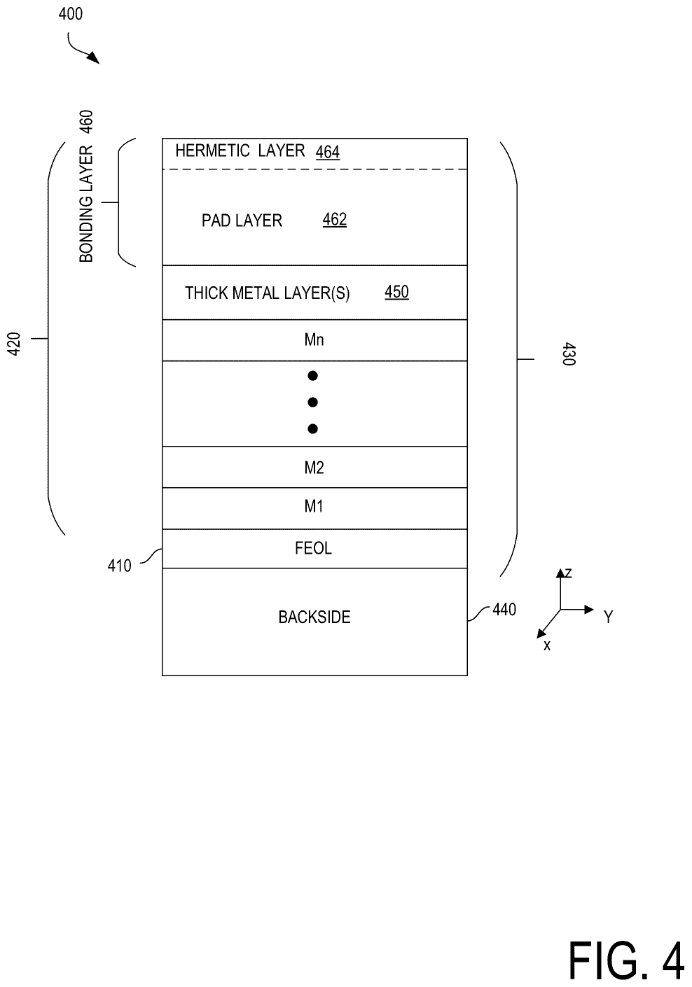

Although the image in FIG. 2 is not drawn to scale, it is intended to show that the upper surface of the semiconductor die 202 is fusion bonded to the upper surface of the semiconductor die 206 (e.g., dielectric to dielectric and copper to copper), and further, that the conductive pads in the semiconductor die 202 line up with the respective conductive pads in the semiconductor die 206. Additionally, as illustrated in the area 212, it is intentionally depicted that the structure(s) in the semiconductor die 202 do not need to line up with the structure(s) in the semiconductor die 206, and this is because the upper surfaces of the semiconductor dies are defined by a layer of a hermetic material (hermetic layer 214 and hermetic layer 216) overlaid on a layer comprising oxide or a layer comprising dielectric material. These two layers (the hermetic layer plus the oxide/dielectric layer) are sometimes collectively referred to as a “bonding layer,” which is described in more detail in connection with FIG. 4. Other ways to describe the zoomed area 212 are that the two MSRs are misaligned, or that a first structure in the first semiconductor die 202 abuts against the MSR layer on the second semiconductor die 206 at a first location, and a second structure in the second semiconductor die 206 abuts against the MSR layer on the first semiconductor die 202 at a second location, and the first location is not the same as the second location. Another way to describe the zoomed area 212 is that there is no copper contiguous path between a first structure 107 in the first semiconductor die 202 and a second structure 107 in the second semiconductor die 206; in other words, the guard ring/MSR is typically not electrically connected to support electrical communication.

As used herein, the hermetic material comprises a silicon nitride (SiN), a silicon carbon nitride (SiCN), or a silicon carbide (SiC). Said differently, the hermetic material comprises silicon plus at least one of carbon (up to 25%) or nitrogen (up to 20%), or silicon (up to 30%) and (up to 40%) oxygen. As may be appreciated by those with skill in the art, moisture paths 210 (indicated with arrows 210-1, 210-2, 210,3, 210-4, 210-5, and 210-6) can migrate through non-hermetic materials, but are blocked by hermetic materials. As indicated with the cartoon arrow, in practice, the moisture paths 210 are not limited to the left side, but surround the semiconductor die 102/202. As illustrated in FIG. 2, the moisture path 210 migration is also blocked by the copper wall structures that extend substantially perpendicularly from the chiplet regions to the respective upper surfaces. Moreover, since the upper surfaces of the first semiconductor die 102 and the second semiconductor die 106 have a layer of hermetic material (hermetic layer 214 and hermetic layer 216) thereon, even when the copper wall structure(s) in the semiconductor die 202 do not line up with the copper wall structure(s) in the semiconductor die 206, the hermetic layers 214/216 block moisture paths 210 migration into the semiconductor assembly/multi-die assembly 200, and block copper migration from occurring between conductive pads.

The hermetic material is overlaid on an oxide layer (see FIG. 4 for a more complete description). The hermetic layer has a thickness in a range of 50 nanometers +/−10% to 1 micron +/−10%. The oxide layer, or layer comprising oxide, has a thickness of greater than 2 microns; and, in various embodiments, the oxide layer thickness may be 4 microns +/−10%. The thickness of the oxide/dielectric layer enables creating “taller” bond pads (e.g., conductive pads with thickness 218, wherein thickness 218 may be 4 microns +/−10%).

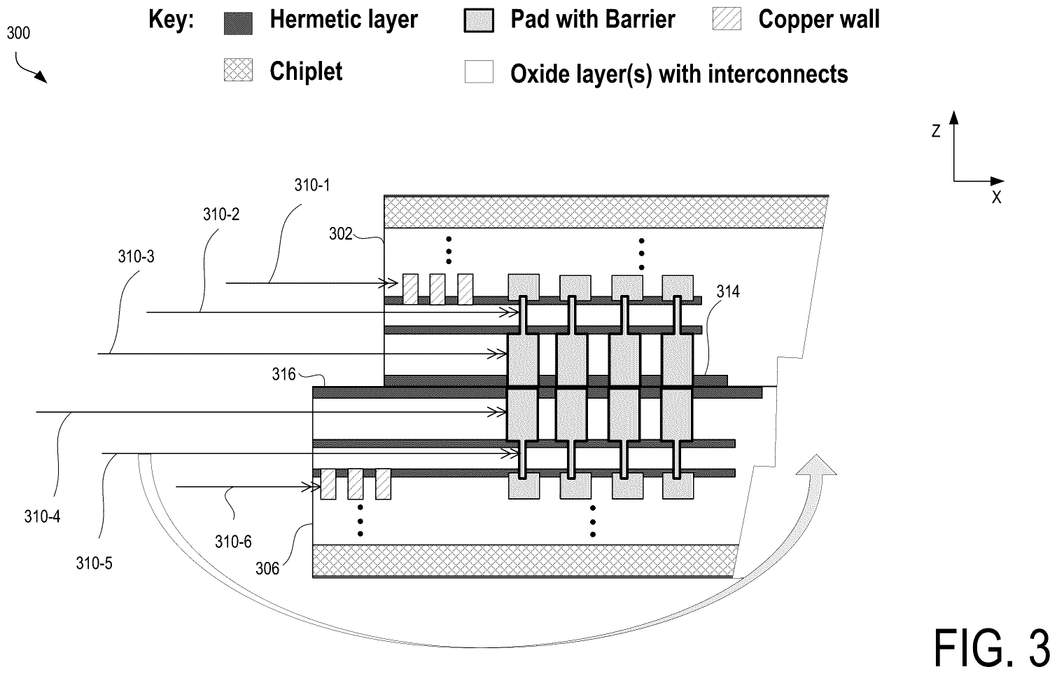

Turning to FIG. 3, the multi-die assembly 300 is very similar to the multi-die assembly 200, with the difference being that the moisture seal structure is not present in the semiconductor die 302 or in the semiconductor die 306. The oxide layer (or layer comprising oxide) has the same thickness as that of FIG. 2, again enabling the “taller” bond pads (e.g., conductive pads with thickness 318, wherein thickness 318 may be 4 microns +/−10%). Moisture 310 (indicated with arrows 310-1, 310-2, 310,3, 310-4, 310-5, and 310-6) can migrate through the oxides and other similar non-hermetic materials. Comparing FIG. 2 to FIG. 3, moisture at arrows 310-3 and 310-4 travel all the way into the periphery of a conductive pad in embodiments configured as FIG. 3. The conductive pads have a coating of a hermetic material around their periphery, as shown. However, the barrier metal around the conductive pad protects it from being vulnerable to moisture and Cu migration.

FIG. 4 provides a schematic illustration of a cross-sectional view of an example integrated circuit device 400 (e.g., a semiconductor die), according to some embodiments of the present disclosure.

Embodiments described herein may include front-end-of-line (FEOL) semiconductor processing and structures. FEOL may be a first portion of IC fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may also include back end of line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL may include contacts, insulating layers (dielectrics), metal levels, and bonding sites for chip-to-package connections. In the BEOL part of the fabrication stage contacts (pads), interconnect wires, vias and dielectric structures are formed.

Embodiments described herein may be applicable to FEOL processing and structures, BEOL processing and structures, or both FEOL and BEOL processing and structures. Although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

As shown in FIG. 4, the IC device 400 may include a front side 430 comprising a FEOL portion 410 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL portion 410 may include, for example, one or more other layers or structures associated with the semiconductor devices and circuits. For example, the FEOL portion 410 can also include a substrate and one or more dielectric layers that surround active and/or conductive portions of the devices and circuits. The FEOL portion may also include one or more conductive contacts that provide electrical contact to transistor elements such as gate structures, drain regions, or source regions. The FEOL portion may also include local interconnect (e.g., vias or lines) that connect contacts to interconnect features within the BEOL portion 420.

The front side 430 of the IC device 400 also includes the BEOL portion 420 including various metal interconnect layers (e.g., metal 1 through metal n, where n is any suitable integer) and thick metal layer(s) 450 comprising one or more metal layers having one or more thickness that are greater than the thicknesses of the lower metal layers (e.g., metal 1 through metal n). Various metal layers of the BEOL portion 420 may be used to interconnect the various inputs and outputs of the FEOL portion 410.

Generally speaking, each of the metal interconnect layers of the BEOL portion 420, e.g., each of the layers M1-Mn and thick metal layer(s) 450 (sometimes referred to as giant metal layers) shown in FIG. 4, may include a via portion and a trench/interconnect portion. Typically, the trench portion of a metal layer is above the via portion, but, in other embodiments, a trench portion may be provided below a via portion of any given metal layer of the BEOL portion 420. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL portion 420, e.g., layers M1-Mn or thick metal layer(s) 450 shown in FIG. 4, may include certain patterns of conductive metals, e.g., copper (Cu), aluminum (Al), Tungsten (W), or metal alloys, or more generally, patterns of an electrically conductive material, formed in an insulating medium such as an interlayer dielectric (ILD). The insulating medium may include any suitable ILD materials such as silicon oxide, silicon nitride, silicon carbon nitride, silicon carbide, aluminum oxide, and/or silicon oxynitride. In various embodiments, the insulating medium may have sufficient transparency for IR light (in some embodiments, the IR light may have a wavelength of 1-2 microns) to pass through to facilitate detection of fiducials. In various embodiments, any one or more of these layers may additionally include active devices (e.g., transistors, diodes) and/or passive devices (e.g., capacitors, resistors, inductors).

The upper surface of the semiconductor dies (IC device 400) are characterized by a substantially planar surface. In various embodiments, a bonding layer 460 may be formed at the top surface of the IC device 400. The bonding layer 460 may include, e.g., various electrical contacts (e.g., conductive bumps, conductive pads, etc.) that may be to electrically connect to corresponding electrical contacts of another IC device in a hybrid bonding process. In a non-limiting example, the bonding layer 460 is further distinguished or characterized by a first sub layer (pad layer 462) comprising silicon and oxygen, and a second sub layer (hermetic layer 464) that defines the surface. The first sub layer may be a thick oxide layer, which may be an oxide surface passivation, such as a silicon oxide (SiOx, 0<x<2). In various embodiments, the first sub layer is not hermetic. The second sub layer is thinner than the first sub layer, defines the surface of a respective semiconductor die or IC device 400, and comprises a hermetic material; as mentioned above, the hermetic material comprises a silicon nitride (SiN), a silicon carbon nitride (SiCN), or a silicon carbide (SiC).

The aforementioned conductive pads or “tall” pads are formed in the bonding layer 460, situated in the first sub layer and second sub layer, as described above and illustrated.

The IC device 400 may also include a backside 440. For example, the backside 440 may formed on the opposite side of a wafer from the front side 430. In various embodiments, the backside 440 may include any suitable elements to assist operation of the IC device 400. For example, the backside 340 may include various metal layers to deliver power to logic of the FEOL portion 410. In some embodiments, transistors or other circuit elements may be formed on the backside 440 of the IC device 400. In other embodiments, the backside 440 may have conductive bumps or pads to attach the die to a substrate package or motherboard.

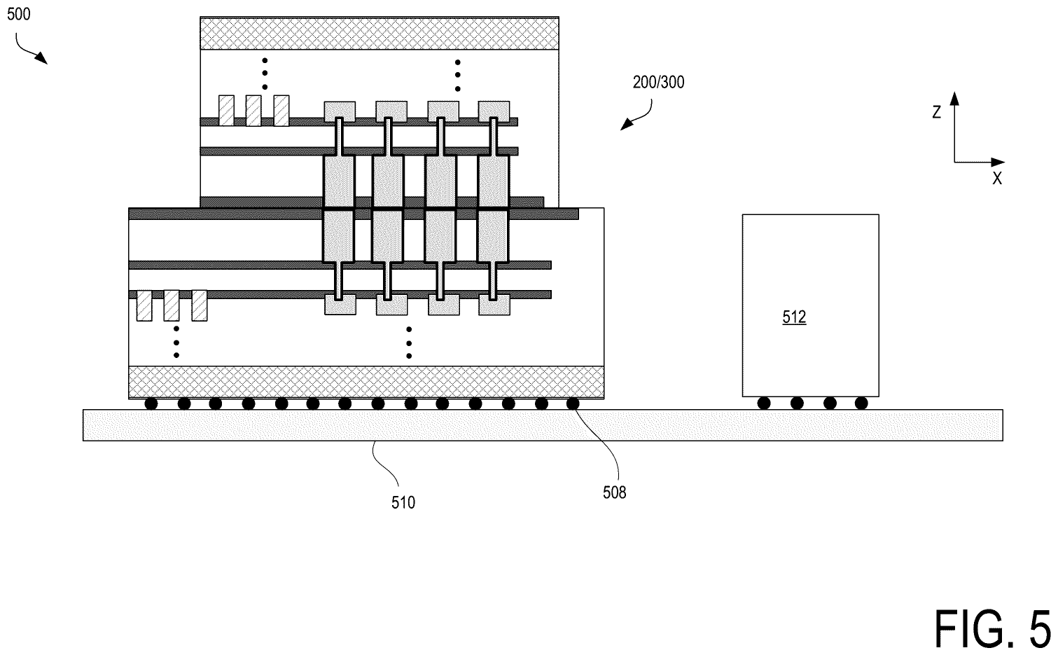

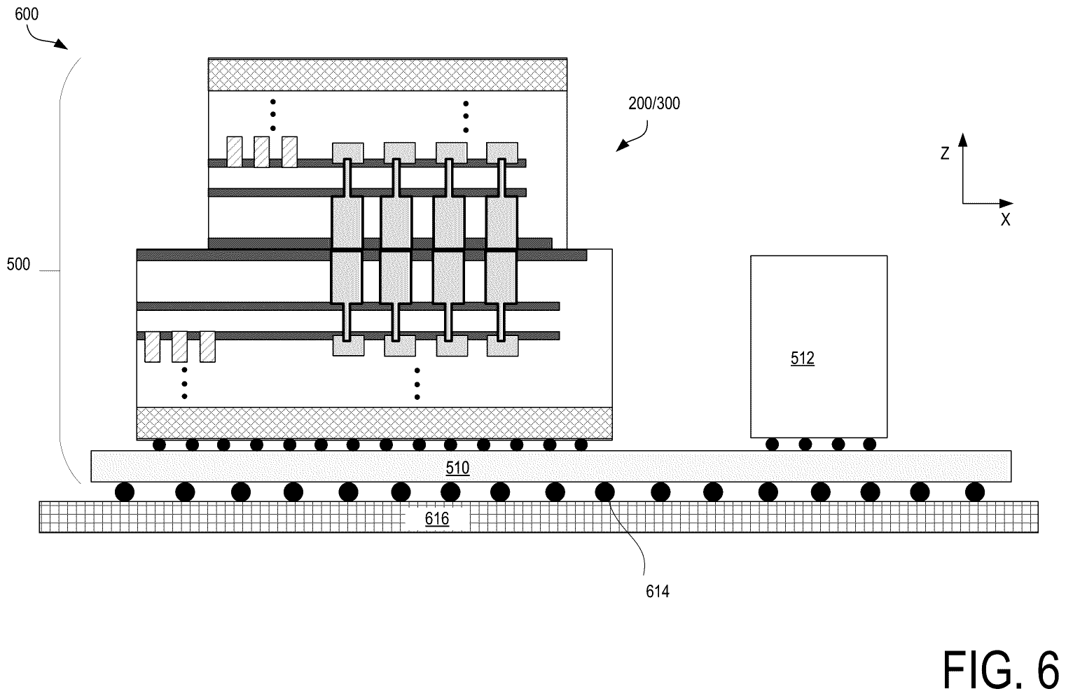

FIG. 5 and FIG. 6 depict examples of the disclosed HBI architecture as it may be implemented in various packages and devices. An exemplary multi-die package 500 may include the multi-die assembly 200 or multi-die assembly 300 with conductive bumps 508 or conductive balls attached on a lower surface of one of the die and attached to a package substrate 510 via the conductive bumps 508. One or more additional integrated circuit (IC) die 512 may also be attached to the package substrate 510. In a device, the embodiment of a multi-die package 500 may have conductive bumps or solder balls 614 attached to the bottom side of the package substrate 510, which may then be attached to a printed circuit board, or motherboard 616.

In various embodiments, the die in the multi-die package 500/600 can be overmolded with an encapsulant. The encapsulant can comprise a molding compound, dielectric materials, metal, ceramic, plastic, or a combination thereof. Additionally, a thermal management solution (not shown) comprising a cooling component such as a vapor chamber, heat pipe, heat sink, or liquid-cooled cold plate may be attached to a multi-die package 500/600. As part of a thermal management solution, a thermal conduction layer interface material (TIM) may be located over the die. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

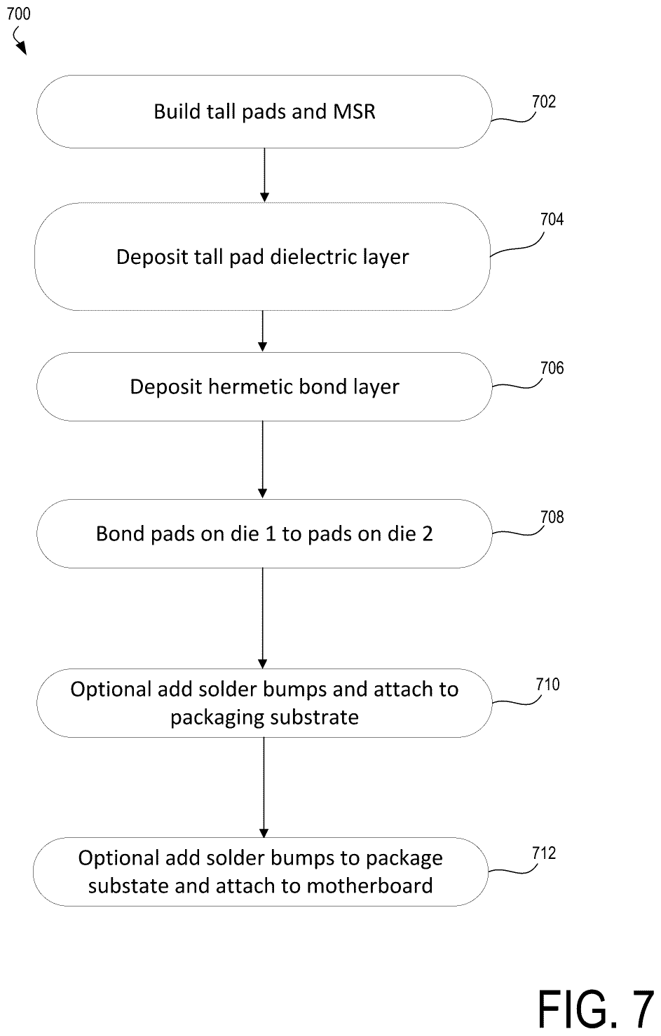

FIG. 7 is a method for making and implementing the hybrid bonding interconnect (HBI) architectures for scalability. At 702, “tall” bond pads are built on an uppermost thick metal layer 450, wherein the meaning of “tall” is defined above. At 702, if the moisture seal ring (MSR) is implemented, the structures that define the copper wall or MSR are also built up.

At 704, a dielectric layer, the aforementioned first sub layer/pad layer 462, or oxide surface passivation, such as a silicon oxide (SiOx, 0<x<2), is deposited over the tall bond pads and MSR structures.

At 706, the hermetic layer 464 comprising the above defined hermetic material is overlaid on the pad layer 462. The tasks of 702-706 are performed for a first semiconductor die and a second semiconductor die. At 708, the first semiconductor die is flipped, and its upper surface is fusion bonded to the upper surface of the second semiconductor die, using the herein described

HBI architectures and methodology. Optionally, at 710, a multi-die package can be created by adding solder bumps or conductive bumps 508 to the multi-die assembly created at 708 and attaching it to a package substrate 510 (multi-die package 500). Also, optionally, at 712, a device can be created by adding solder balls 614 to the multi-die package created at 710 and attaching it to a motherboard 616 (embodiment 600).

Thus, hybrid bonding interconnect (HBI) architectures and methods for scalability have been described. To summarize, unique features of this invention that may be seen in a SEM image include: (1) a semiconductor die surface comprising a first bonding sub layer defined by a layer of silicon and nitride or silicon and carbon, or both, having a thickness less than 1 micron; (2) a second bonding sub layer under the first bonding sub layer comprising silicon and oxide with a thickness greater than 2 microns; and (3) “tall” bond pads that are conductive pads with a thickness greater than 2 microns located in the second bonding sub layer and exposed at the first bonding sub layer. The following description and associated figures provide more detail for components referenced hereinabove.

<<change to 8>>

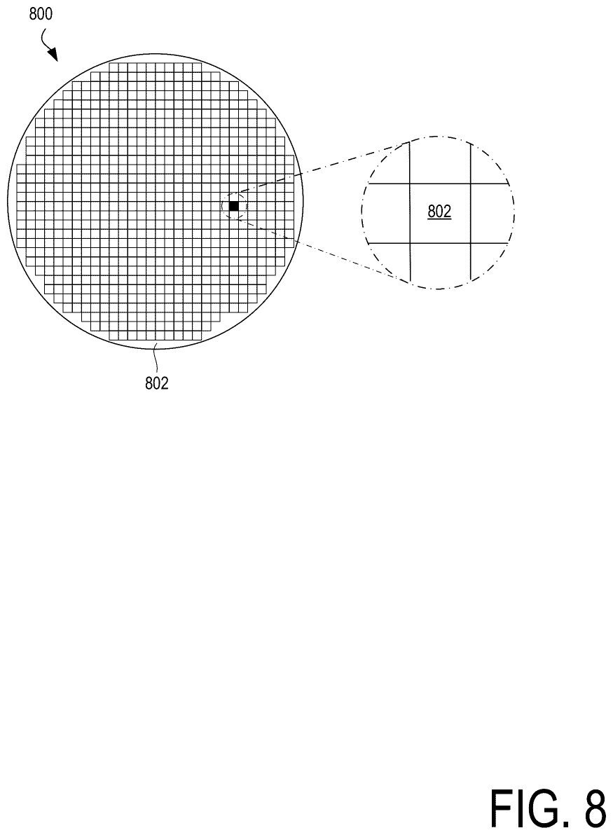

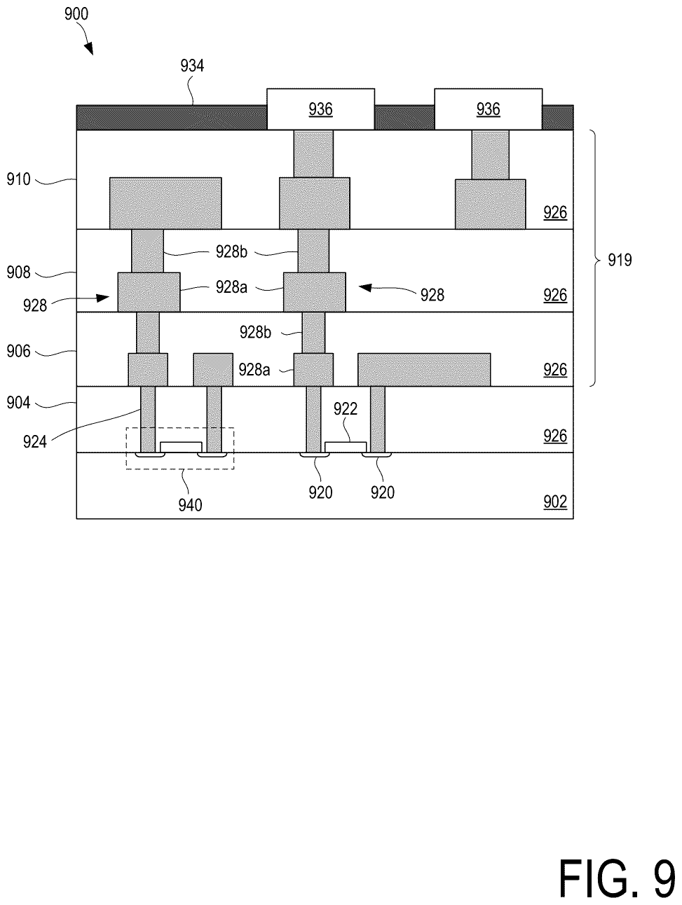

FIG. 8 is a top view of a wafer 800 and dies 802 that may be included in any of the embodiments disclosed herein. The wafer 800 may be composed of semiconductor material and may include one or more dies 802 formed on a surface of the wafer 800. After the fabrication of the integrated circuit components on the wafer 800 is complete, the wafer 800 may undergo a singulation process in which the dies 802 are separated from one another to provide discrete “chips” or destined for a packaged integrated circuit component. The individual dies 802, comprising an integrated circuit component, may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 802. For example, a memory array formed by multiple memory devices may be formed on a same die 802 as a processor unit (e.g., the processor unit 1202 of FIG. 12) or other logic that is configured to store information in the memory devices or execute instructions stored in the memory array. In some embodiments, a die 802 may be attached to a wafer 800 that includes other die, and the wafer 800 is subsequently singulated, this manufacturing procedure is referred to as a die-to-wafer assembly technique.

FIG. 9 is a cross-sectional side view of an integrated circuit 900 that may be included in any of the embodiments disclosed herein. One or more of the integrated circuits 900 may be included in one or more dies 802 (FIG. 8). The integrated circuit 900 may be formed on a die substrate 902 (e.g., the wafer 800 of FIG. 8) and may be included in a die (e.g., the die 802 of FIG. 8).

The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit 900 may be used. The die substrate 902 may be part of a singulated die (e.g., the dies 802 of FIG. 8) or a wafer (e.g., the wafer 800 of FIG. 8).

The integrated circuit 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920.

The gate 922 may be formed of at least two layers, a gate dielectric, and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may comprise a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be conducted to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuits having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928a/b of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit 900 with another component (e.g., a printed circuit board). The integrated circuit 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit 900 is a double-sided die, the integrated circuit 900 may include another metallization stack (not shown) on the opposite side of the device layer(s) 904. This metallization stack may include multiple interconnect layers as discussed above with reference to the interconnect layers 906-910, to provide electrically conductive paths (e.g., including conductive lines and vias) between the device layer(s) 904 and additional conductive contacts (not shown) on the opposite side of the integrated circuit 900 from the conductive contacts 936.

In other embodiments in which the integrated circuit 900 is a double-sided die, the integrated circuit 900 may include one or more through-silicon vias (TSVs) through the die substrate 902; these TSVs may make contact with the device layer(s) 904, and may provide electrically conductive paths between the device layer(s) 904 and additional conductive contacts (not shown) on the opposite side of the integrated circuit 900 from the conductive contacts 936. In some embodiments, TSVs extending through the substrate can be used for routing power and ground signals from conductive contacts on the opposite side of the integrated circuit 900 from the conductive contacts 936 to the transistors 940 and any other components integrated into the die of the integrated circuit 900, and the metallization stack 919 can be used to route I/O signals from the conductive contacts 936 to transistors 940 and any other components integrated into the die of the integrated circuit 900.

Multiple integrated circuits 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

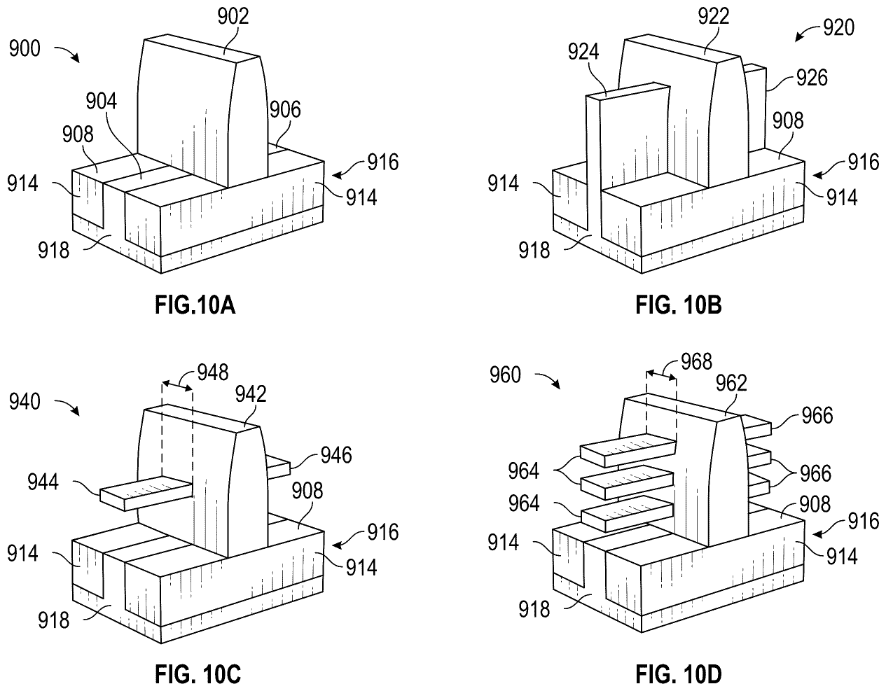

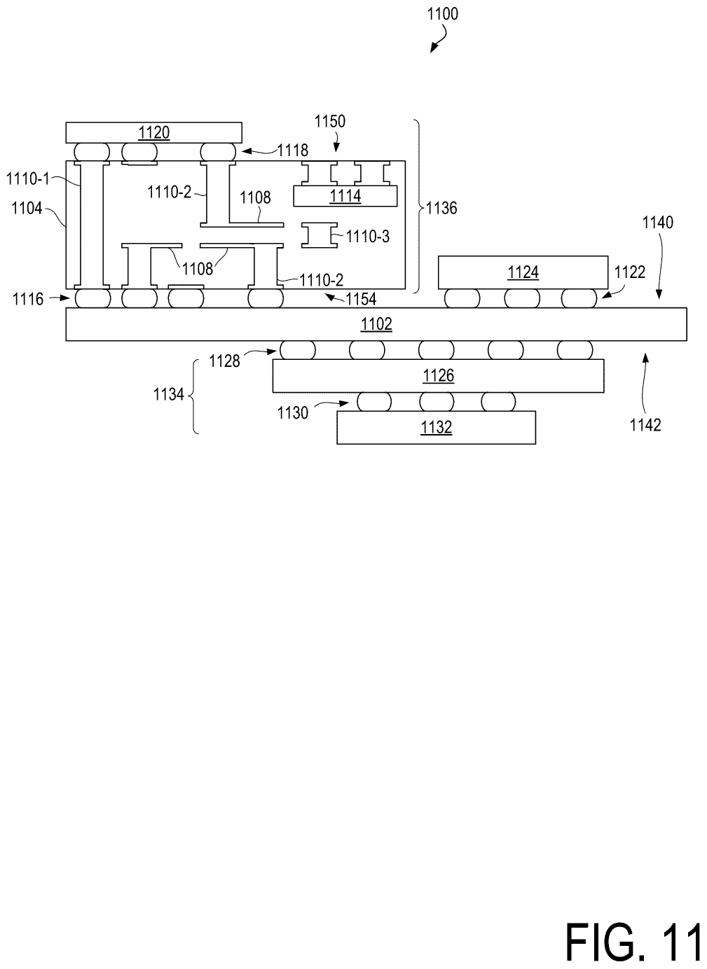

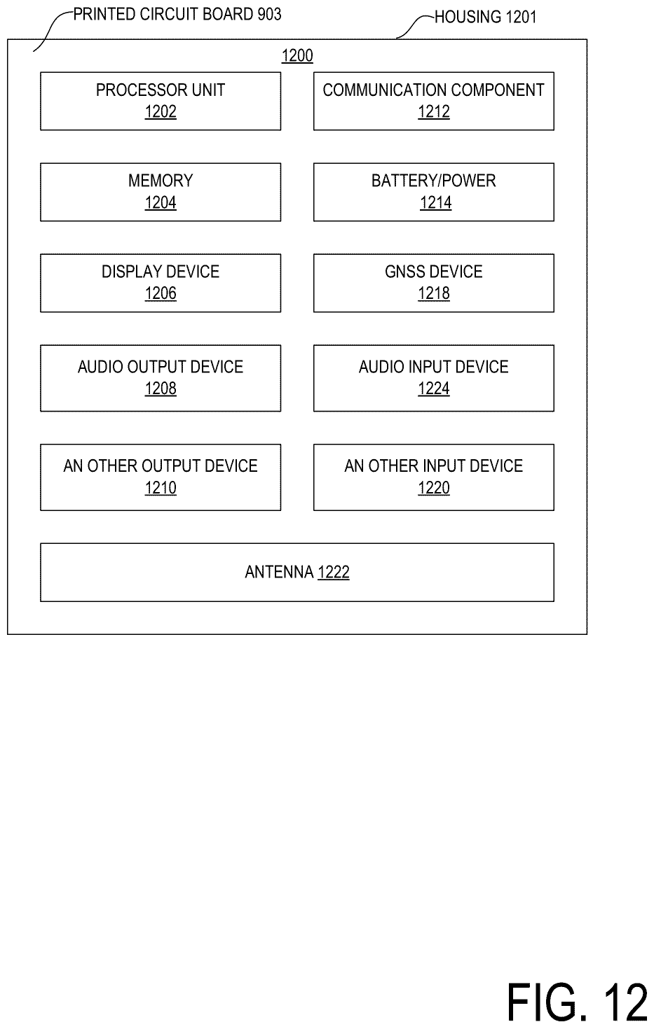

FIGS. 10A-10D are simplified perspective views of example planar, FinFET, gate-all-around, and stacked gate-all-around transistors. The transistors illustrated in FIGS. 10A-10D are formed on a substrate 1016 having a surface 1008. Isolation regions 1014 separate the source and drain regions of the transistors from other transistors and from a bulk region 1018 of the substrate 1016.

FIG. 10A is a perspective view of an example planar transistor 1000 comprising a gate 1002 that controls current flow between a source region 1004 and a drain region 1006. The transistor 1000 is planar in that the source region 1004 and the drain region 1006 are planar with respect to the substrate surface 1008.

FIG. 10B is a perspective view of an example FinFET transistor 1020 comprising a gate 1022 that controls current flow between a source region 1024 and a drain region 1026. The transistor 1020 is non-planar in that the source region 1024 and the drain region 1026 comprise “fins” that extend upwards from the substrate surface 1008. As the gate 1022 encompasses three sides of the semiconductor fin that extends from the source region 1024 to the drain region 1026, the transistor 1020 can be considered a tri-gate transistor. FIG. 10B illustrates one S/D fin extending through the gate 1022, but multiple S/D fins can extend through the gate of a FinFET transistor.

FIG. 10C is a perspective view of a gate-all-around (GAA) transistor 1040 comprising a gate 1042 that controls current flow between a source region 1044 and a drain region 1046. The transistor 1040 is non-planar in that the source region 1044 and the drain region 1046 are elevated from the substrate surface 1008.

FIG. 10D is a perspective view of a GAA transistor 1060 comprising a gate 1062 that controls current flow between multiple elevated source regions 1064 and multiple elevated drain regions 1066. The transistor 1060 is a stacked GAA transistor as the gate controls the flow of current between multiple elevated S/D regions stacked on top of each other. The transistors 1040 and 1060 are considered gate-all-around transistors as the gates encompass all sides of the semiconductor portions that extend from the source regions to the drain regions. The transistors 1040 and 1060 can alternatively be referred to as nanowire, nanosheet, or nanoribbon transistors depending on the width (e.g., widths 1048 and 1068 of transistors 1040 and 1060, respectively) of the semiconductor portions extending through the gate.

FIG. 11 is a cross-sectional side view of a microelectronic assembly 1100 that may include any of the embodiments disclosed herein. The microelectronic assembly 1100 includes multiple integrated circuit components disposed on a circuit board 1102 (which may be a motherboard, system board, mainboard, etc.). The microelectronic assembly 1100 may include components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The microelectronic assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit component that includes one or more integrated circuit dies (e.g., the die 802 of FIG. 8, the integrated circuit 900 of FIG. 9) and/or one or more other suitable components.

The unpackaged integrated circuit component 1120 comprises solder bumps attached to contacts on the die. The solder bumps allow the die to be directly attached to the interposer 1104. In embodiments where the integrated circuit component 1120 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through-silicon vias (TSV) extending through the silicon interposer can connect connections on the first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the disclosed embodiments, semiconductor assemblies, package assemblies, microelectronic assemblies 1100, integrated circuit components 1120, integrated circuits 900, integrated circuit dies 802, or structures disclosed herein. A number of components are illustrated in FIG. 12 as included in the electrical device 1200, but any one or more of these components may be omitted or duplicated, as suitable for the application. In some embodiments, some or all the components included in the electrical device 1200 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processor units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include power supply such as a battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is a semiconductor die, comprising: a substrate comprising integrated circuitry; a layer on the substrate, the layer comprising a first sub layer including silicon and oxygen, and a second sub layer including silicon and at least one of nitrogen or carbon, and wherein the second sub layer defines a surface; and at least one conductive pad in the layer that is coupled to the integrated circuitry and exposed at the surface.

Example 2 includes the subject matter of Example 1, wherein the at least one conductive pad includes a barrier metal.

Example 3 includes the subject matter of Example 1 or Example 2, wherein the second sub layer is a hermetic material.

Example 4 includes the subject matter of any one of Examples 1-3, wherein the first sub layer has a thickness greater than two microns.

Example 5 includes the subject matter of any one of Examples 1-3, wherein the first sub layer has a thickness of four microns +/−10%.

Example 6 includes the subject matter of any one of Examples 1-3, wherein the second sub layer has a thickness in a range of 50 nanometers +/−10% to 1 micron +/−10%.

Example 7 includes the subject matter of any one of Examples 1-3, wherein the conductive pad has a height of 4 microns +/−20%.

Example 8 includes the subject matter of Example 1, further comprising a structure in the layer, between the at least one conductive pad and an edge of the substrate.

Example 9 includes the subject matter of Example 8, wherein the structure has a contiguous path from the substrate to the surface.

Example 10 includes the subject matter of Example 8, wherein the structure comprises copper.

Example 11 is a semiconductor assembly comprising: a first semiconductor die with a first surface comprising a hermetic material overlaid on a first layer comprising an oxide (or other non-hermetic interlayer dielectric material); a first conductive pad in the first layer comprising oxide and exposed at the first surface; a second semiconductor die with a second surface comprising the hermetic material overlaid on a second layer comprising an oxide; and a second conductive pad in the second layer comprising oxide and exposed at the second surface; wherein the first surface is fusion bonded to the second surface and the first conductive pad is electrically coupled to the second conductive pad.

Example 12 includes the subject matter of Example 11, further comprising: a first structure in the first layer, between the first conductive pad and an edge of the first semiconductor die, and exposed at the first surface; a second structure in the second layer, between the second conductive pad and an edge of the second semiconductor die and exposed at the second surface; and wherein the first structure abuts against the hermetic material at a first location on the second surface; and the second structure abuts against the hermetic material at a second location on the first surface; wherein the first location is different from the second location.

Example 13 includes the subject matter of Example 11, wherein the hermetic material comprises silicon and nitrogen or carbon.

Example 14 includes the subject matter of any one of Examples 11-13, wherein the first layer plus the hermetic material and the second layer plus the hermetic material have a thickness greater than four microns +/−20%.

Example 15 includes the subject matter of any one of Examples 11-13, wherein the first layer and the second layer have a thickness of two microns +/−10%.

Example 16 includes the subject matter of any one of Examples 11-13, wherein the hermetic material has a thickness in a range of 50 nanometers +/−10% to 1 micron +/−10%.

Example 17 includes the subject matter of any one of Examples 11-13, wherein the hermetic material has a thickness of 200 nanometers +/−20%.

Example 18 is a device, comprising: a semiconductor assembly comprising: a first semiconductor die with a first surface comprising a hermetic material overlaid on a first layer comprising an oxide; a first conductive pad in the first layer comprising oxide and exposed at the first surface; a second semiconductor die with a second surface comprising the hermetic material overlaid on a second layer comprising an oxide; a second conductive pad in the second layer comprising oxide and exposed at the second surface; wherein the first surface is fusion bonded to the second surface and the first conductive pad is electrically coupled to the second conductive pad; a plurality of conductive bumps on a surface of the semiconductor assembly; and a package substrate attached to the semiconductor assembly via the plurality of conductive bumps.

Example 19 includes the subject matter of Example 18, further comprising: an integrated circuit (IC) die attached to the package substrate; and a power supply attached to the package substrate.

Example 20 includes the subject matter of Example 18, further comprising a cooling component attached to the semiconductor assembly.

What is claimed is:

1. A semiconductor die, comprising:
a substrate comprising integrated circuitry;
a layer on the substrate, the layer comprising a first sub layer including silicon and oxygen, and a second sub layer including silicon and at least one of nitrogen or carbon, and wherein the second sub layer defines a surface; and
at least one conductive pad in the layer that is coupled to the integrated circuitry and exposed at the surface.

2. The semiconductor die of claim 1, wherein the at least one conductive pad has a height of four microns +/−20%.

3. The semiconductor die of claim 1, wherein the second sub layer is a hermetic material.

4. The semiconductor die of claim 1, wherein the first sub layer has a thickness greater than two microns.

5. The semiconductor die of claim 1, wherein the first sub layer has a thickness of four microns +/−10%.

6. The semiconductor die of claim 1, wherein the second sub layer has a thickness in a range of 50 nanometers +/−10% to 1 micron +/−10%.

7. The semiconductor die of claim 1, wherein the at least one conductive pad has a perimeter comprising a metal layer.

8. The semiconductor die of claim 1, further comprising a structure in the layer, between the at least one conductive pad and an edge of the substrate.

9. The semiconductor die of claim 8, wherein the structure has a contiguous path from the substrate to the surface.

10. The semiconductor die of claim 8, wherein the structure comprises copper.

11. A semiconductor assembly comprising:
a first semiconductor die with a first surface comprising a hermetic material overlaid on a first layer comprising a dielectric material;
a first conductive pad in the first layer and exposed at the first surface;
a second semiconductor die with a second surface comprising the hermetic material overlaid on a second layer comprising a second dielectric material; and
a second conductive pad in the second layer and exposed at the second surface;
wherein the first surface is fusion bonded to the second surface and the first conductive pad is electrically coupled to the second conductive pad.

12. The semiconductor assembly of claim 11, further comprising:
a first structure in the first layer, between the first conductive pad and an edge of the first semiconductor die, and exposed at the first surface;
a second structure in the second layer, between the second conductive pad and an edge of the second semiconductor die and exposed at the second surface; and
wherein the first structure abuts the hermetic material at a first location on the second surface; and the second structure abuts the hermetic material at a second location on the first surface;
wherein the first location is different from the second location.

13. The semiconductor assembly of claim 11, wherein the hermetic material comprises silicon and nitrogen or silicon and carbon.

14. The semiconductor assembly of claim 11, wherein the first layer comprising oxide and the second layer comprising oxide have a thickness greater than two microns.

15. The semiconductor assembly of claim 11, wherein the first layer and the second layer have a thickness of 4 microns +/−20%.

16. The semiconductor assembly of claim 11, wherein the hermetic material has a thickness in a range of 50 nanometers +/−10% to 1 micron +/−10%.

17. The semiconductor assembly of claim 11, wherein the hermetic material has a thickness of 200 nanometers +/−20%.

18. A device, comprising:
a semiconductor assembly comprising: a first semiconductor die with a first surface comprising a hermetic material overlaid on a first layer comprising an oxide; a first conductive pad in the first layer comprising oxide and exposed at the first surface; a second semiconductor die with a second surface comprising the hermetic material overlaid on a second layer comprising an oxide; a second conductive pad in the second layer comprising oxide and exposed at the second surface; wherein the first surface is fusion bonded to the second surface and the first conductive pad is electrically coupled to the second conductive pad;
a plurality of conductive bumps on a surface of the semiconductor assembly; and
a package substrate attached to the semiconductor assembly via the plurality of conductive bumps.

19. The device of claim 18, further comprising:
an integrated circuit (IC) die attached to the package substrate; and
a power supply attached to the package substrate.

20. The device of claim 18, further comprising a cooling component attached to the semiconductor assembly.
